(19) United States
(12) Patent Application Publication
(10) Pub. No.: US 2025/0040072 A1
(43) Pub. Date: Jan. 30, 2025

(54) HOUSING OR PORTION OF A HOUSING FOR AN ELECTRONIC CIRCUIT

(71) Applicant: ELRINGKLINGER AG, Dettingen/Erms (DE)

(72) Inventors: Bernd TRABER, Dettingen/Erms (DE); Peter SCHOELZEL, Dettingen/Erms (DE)

(21) Appl. No.: 18/714,177

(22) PCT Filed: Nov. 29, 2022
(86) PCT No.: PCT/EP2022/083732

§ 371 Date: May 29, 2024

(30) Foreign Application Priority Data
Nov. 29, 2021 (DE) 10 2021 131 324.4

(51) Int. Cl. H05K 5/04; H05K 5/00; H05K 7/20; H05K 9/00

(52) U.S. Cl. CPC H05K 5/04; H05K 5/0026; H05K 7/2039; H05K 9/0007

(57) ABSTRACT

A housing or a portion of a housing for an electronic circuit, preferably an electrical system component of a vehicle. In order to provide a housing for an electronic circuit, preferably an electrical system component of a vehicle and in particular a battery storage device, which has improved properties, even beyond a thermal runaway or comparable exceptional thermal conditions, it is proposed for the housing or a portion of the housing to have a surface, which is embodied as a shielding device with an insulating layer facing the electronic circuit and a metallic outer layer, and for the housing or a portion of the housing to have a heat sink.

### FIELD OF THE INVENTION

The present invention relates to housing or a portion of a housing for an electronic circuit, preferably an electrical system component of a vehicle.

### BACKGROUND OF THE INVENTION

Such an electrical system component in a vehicle is understood to include, among other things, high-voltage battery storage devices, voltage converters or generators, etc. What these electrical system components have in common is that they are subject to electrical losses during operation. These electrical losses primarily occur in the form of heat. In addition, special safety risks must be taken into account for these electrical system components due to high thermal loads. This applies in particular to high-voltage battery storage devices due to their central technical importance for a vehicle as well as to their size and proximity to a passenger compartment.

Among a vehicle's electrical system components, a high-voltage battery storage device is a particularly important element, which must meet greater requirements and at the same time involves special risks even when not in active operation. Each high-voltage battery storage device has interconnected modules or elementary storage cells that are connected to external connections via a switching and control unit and anchored in a housing that is closed by a cover. With regard to the above-mentioned technical requirements and safety risks, EP 2 244 318 B1, for example, discloses design-related protective measures for a battery pack housing, which constitutes a housing for an electronic circuit as defined by the present invention, in a vehicle in the event of a sharp increase in pressure and temperature inside the housing of a battery pack. These measures are provided as protection in the event of what is known as a thermal runaway of a battery cell or “thermal runaway event”. Hot gases escaping from relief openings are diverted away from a passenger compartment in a targeted way by means of thermal insulation in order to permit a passenger to safely exit the vehicle even in the catastrophic event of a thermal runaway. The housing in this case is still considered to be a closed housing.

The object of the present invention is to provide a housing or portion of a housing for an electronic circuit, preferably an electrical system component of a vehicle and in particular a battery storage device, which has improved properties, even beyond a thermal runaway or comparable exceptional thermal conditions, and also has advantages in regular operating conditions.

### SUMMARY OF THE INVENTION

According to the invention, the housing or a portion of the housing has an outer surface, which is embodied as a shielding device with an insulating layer facing the electronic circuit and a metallic outer layer, and the housing or a portion of the housing has a heat sink.

The present invention essentially draws on the knowledge and experience gained in the field of thermal and acoustic shielding of an exhaust line of an internal combustion engine. According to the current state of the art shielding systems are known for thermal and/or acoustic shielding of emission sources and are widely used in the sphere of internal combustion engines, i.e. from the internal combustion engine itself to an exhaust pipe. In series production, such shielding systems are widely used in motor vehicles with internal combustion engines, in particular as thermal insulation for exhaust gas-carrying components and are also used to reduce acoustic emission.

As a rule, a shielding system consists of at least two layers: an at least single-layer metallic outer layer in a smooth or dimpled design that is possibly also perforated on a free outer side, as well as an insulating layer, e.g. in the form of foams or fleeces, which in the installed state, is positioned facing an emitting component. The use of several stacked metal layers is also known, e.g. in order to achieve sufficient pressure tightness despite the presence of the acoustically effective perforation of the free outer side. For example, the two different layers are connected by adhesive, staples, or clamps. This type of shielding system is also known as so-called direct shielding. In the case of an electronic circuit contained in a housing, such a shielding device significantly reduces thermal and/or acoustic emission at an outer surface of the housing and not just in the event of a malfunction.

In a closed housing that encloses a circuit that is in operation and is thus producing electrical heat loss, the above-mentioned sub-feature would reliably protect a certain area of an adjacent region from heat and/or sound. At the same time, however, an accumulation of heat within this housing could lead to an increase in the internal temperature. It is known that the average life expectancy of electronic components is strongly dependent on the ambient temperature. It is therefore very advantageous to supplement a spatially directed protection of an adjacent region by means of a targeted removal of electrical heat loss from the closed housing. A housing according to the invention therefore has a combination of at least one shielding device and at least one heat sink.

According to some modifications, at least one outer surface of the housing is provided with a shielding device or is formed by the shielding device. The present modification of the invention thus advantageously modifies an existing housing by attaching a shielding device to it or in that at least one surface of the housing is formed by a shielding device. The latter alternative includes the possibility of replacing a housing surface with a shielding device as well as providing at least one housing part in the form of a shielding device.

Advantageously, at least one outer surface of the housing or a portion of the housing is also provided with a heat sink or is formed by a heat sink in a similar way.

In one modification of the invention, the shielding device and/or the heat sink is embodied to be flame-resistant. Preferably, the shielding device and/or the heat sink are flame-retardant.

Alternatively or additionally, the shielding device and/or the heat sink have vibration-damping and/or acoustically damping properties tailored to a specific application. With regard to safety-relevant aspects, both the insulating layer and the metallic support layer of direct shielding systems are thus optimally adapted to the respective requirements. Depending on the requirements of an application, in some embodiments, silicate or ceramic fiber mats with a high thermal and electrical insulating effect and extreme temperature resistance are used as insulating materials. In special embodiments, mats especially developed for use in fire protection applications are also provided, e.g. shielding systems based on calcium magnesium silicate. In addition, shielding systems are also embodied to damp acoustic emissions from the corresponding electrical system components using the above-mentioned direct insulation components in order to significantly reduce these types of emissions in a passenger compartment as well. In this case, technical measures can be used to specifically take passengers' subjective perception into account in order to selectively dampen disturbances in the form of noise, vibration, and/or roughness that are found to be stressful, unpleasant, or even “ugly” in a perceptible transition range from approx. 20 Hz to approx. 100 Hz and an audible range of up to 4,500 Hz, in accordance with an NVH approach. Passive structures with good heat dissipation are generally embodied as metal parts, whereby in addition to copper, aluminum in particular is preferred due to its easy machinability, low weight, low material costs, and high corrosion resistance accompanied by good thermal conductivity. Cast and extruded parts can also be combined with active components such as fans and/or Peltier elements or so-called heat pipes in order to improve heat dissipation. Suitable surface structures can also be used here to dampen noise, vibration or other disturbing phenomena, in particular through open, multi-layered structures on an outer surface.

In a preferred embodiment of the invention, the shielding device and the at least one heat sink are embodied to force a directed heat flow within the closed housing. The thermal losses thus no longer flow out of the housing of the electronic circuit in an essentially equally distributed manner in all spatial directions due to the effect of the shielding device, but instead have a clearly preferred direction and spatial areas with a clear reduction in heat flow. Since thermal losses from electrical system components are already being used as much as possible for conditioning heat transfer media, the overall system efficiency of a vehicle can be increased through directed heat flows, although heat recovery measures do have physical limitations. Heat can only be effectively tapped and utilized via the heat sink in a part of electrical system components that is particularly heated by losses. Thermal losses inevitably occur on non-usable surfaces, which, without a shielding according to the invention with the above-mentioned feature, would flow out to the environment in an undirected, e.g. evenly distributed, manner and technically could not be further utilized.

With regard to the efficiency of the overall system, minimizing the thermal losses in portions of electrical system components that cannot be thermally coupled into the vehicle system or supplied to a targeted heat dissipation system via directed heat flows offers the advantage that fewer heat loss quantities remain and can accumulate in these locations. This can lead to an increase in the amount of usable heat in thermally usable regions and thus to an increase in the efficiency of the overall system. In particular, direct shielding systems provide an optimal basis due to their geometric flexibility along with their ruggedness and variety of design possibilities with regard to the respective shielding effect. In one embodiment of the invention, this effect is further enhanced by at least one heat sink, which can also be embodied to be rugged and optimized.

In a preferred embodiment of the invention, the shielding device and the heat sink or a cooling device are positioned so they are complementary to each other. In one modification, the shielding device and the heat sink or cooling device are even positioned opposite from each other on the closed housing. This specifically minimizes the influence of a portion of the heat loss in a certain spatial direction. A significant reduction of a heat flow toward a passenger compartment, for example, does not cause a significant temperature increase with a heat build-up there, but rather a targeted dissipation of heat loss while improving the effect and efficiency of a cooling device that is positioned, for example, under the passenger compartment. Heat is then dissipated via a floor region, for example, in that the heat is dissipated by free and/or forced convection or transferred to a cooling medium there.

In one modification of the invention, the shielding device and/or the heat sink comprise a cover. In one embodiment of the invention, the shielding device and/or the heat sink are even extended at least partially onto side surfaces of the housing adjacent thereto. Preferably, the shielding device and/or the heat sink are even extended at least to housing portions of a housing bottom and/or cover. For example, starting from a flat cuboid as the housing body, i.e. from a large upper side, narrow side surfaces are also covered in one piece or contiguously with the shielding device or are formed by it so that essentially only an underside is not formed by the shielding device. In this embodiment, an underside and/or a bottom adjoining the side surfaces of the housing is then embodied as a heat sink. This means that heat loss quantities and/or vibrations can only be dissipated in a directed manner via this remaining surface of the cuboid.

According to a significant modification of the invention, the heat sink has a mechanically protective safety material. This safety feature is positioned in the form of a layer between the metallic outer layer and a layer for heat dissipation and serves to increase passive mechanical resistance to damage.

In one modification of the invention, the shielding device has a safety material which is positioned in the form of a layer between the metallic outer layer and the insulating layer. Similarly, in one modification, the heat sink is also equipped with a safety material. Preferably, the shielding device and/or the heat sink are equipped with Kevlar or another safety material. As a result of this measure, predetermined locations of a housing are embodied for increased safety, e.g. to prevent mechanical penetration, in particular by a nail, which could trigger a gradual progressive failure of a heat dissipation and/or a thermal event due to an internal short circuit. According to one embodiment, the shielding device and/or the heat sink is equipped with Kevlar or another safety material for increased safety from mechanical penetration. A safety material is alternatively embodied as protection from chemically active substances, for example an acid.

The present invention thus provides a housing that is embodied to simultaneously increase the efficiency and safety of an electronic circuit, preferably an electrical system component of an electric vehicle, while enhancing an acoustic decoupling and improving cooling with heat dissipation from the electronic circuit while improving operational safety.

### BRIEF DESCRIPTION OF THE DRAWINGS

Other features and advantages of embodiments according to the invention will be explained in greater detail below with reference to exemplary embodiments based on the drawings. In the schematic representations in the drawings:

FIG. 1: shows an illustration of the basic effect of a shielding device with a heat sink on a housing of an electronic circuit that is subject to heat losses;

FIG. 2: shows a three-dimensional view of a known high-voltage battery system for an automotive application with the addition of a shielding device and

FIG. 3: shows a view of a detail of the high-voltage battery system shown in FIG. 2.

### DETAILED DESCRIPTION OF THE INVENTION

The same reference symbols are always used for the same elements throughout the various figures in the drawings. Without limiting the invention, the discussion below refers only to a use in a high-voltage battery storage device of an electric vehicle. The basic approach proposed by the invention can, however, be applied to any closed housing around a thermal energy-emitting device and, in particular, an electrical circuit, in order to achieve thermal protection on the one hand and simultaneously also a targeted heat dissipation in order to significantly reduce the formation of undesirable heat pockets.

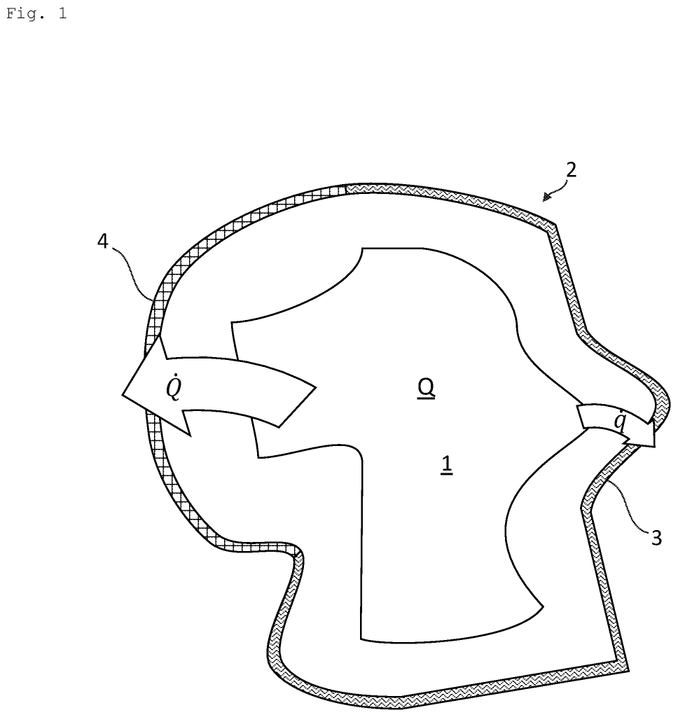

FIG. 1 shows a cross-sectional view of an electronic circuit 1 that is subject to heat losses in a closed housing 2 that can have any three-dimensional form. The housing 2 in this case is partially provided with a shielding device 3 in that the shielding device 3 forms a partial surface of the closed housing 2. In the electronic circuit 1, electrical losses occur, which appear in the form of a quantity of heat Q. In a known housing 2, this quantity of heat Q would flow in all directions in the form of equal-magnitude heat flows \dot{Q} in the direction of a respective temperature drop. The shielding device 3, however, is embodied to force a directed heat flow \dot{Q}, as indicated by the arrows of different sizes in FIG. 1. A heat sink 4 is positioned on the housing 2 so that it is complementary to the shielding device 3. The shielding device 3 therefore ensures that the greatest possible heat flow \dot{Q} flows from the electronic circuit 1, as the source of the heat quantity Q, to the heat sink 4. The heat sink 4 shown here is an active cooling device, for example. By contrast, only a small portion, as a heat flow \dot{q}, penetrates through the shielding device 3 into an outer space of the housing 2.

By equipping the shielding device 3 and/or the heat sink 4 with Kevlar or another safety material in the form of an intermediate layer, for example, increased safety from mechanical penetration, e.g. nail penetration, can also be achieved, i.e. increased resistance to penetration by items such as nails or sharp stones during operation.

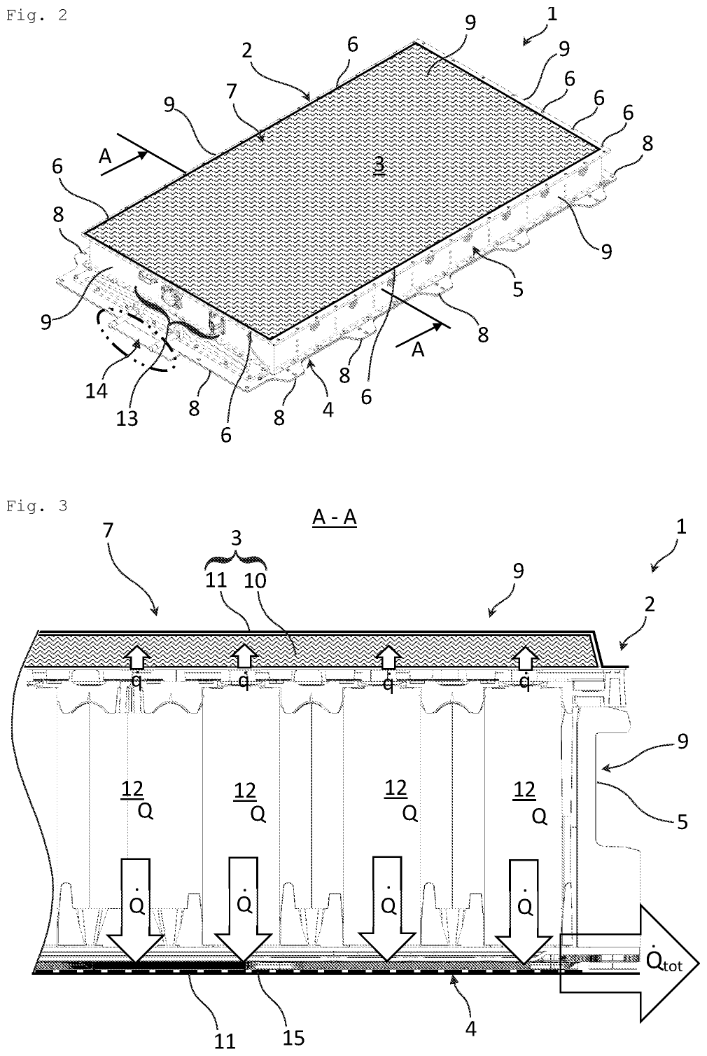

Following this more abstract illustration of the basic effect of a housing 2 embodied according to the invention around an electronic circuit 1 that is subject to losses, the discussion below will—without limiting the application scope of a device according to the invention—address only its use as the housing 2 of a battery system made up of modules in a purely electric vehicle that is not itself shown in detail in the drawing. The diagram in FIG. 2 shows a perspective view of a known high-voltage battery system 1 as an electrical circuit, which emits considerable losses in the form of heat during charging and discharging. The high-voltage battery system 1 is embodied for an automotive application with an output voltage of 400 V and currents with an amperage of up to approx. 1,000 A. The high-voltage battery system 1 has a closed housing 2 in the form of a flat cuboid in which a carrier for elementary storage cells that are not shown in detail or modules constructed from them that is embodied in the form of a flat tray 5 is connected in a sealed fashion to a cover 7 via numerous screw connections 6. In an installed position, the housing 2 is anchored to the chassis of a vehicle by means of flanges 8 so that the cover 7 is positioned adjacent to a passenger compartment that is not shown in detail. Stated more precisely, the cover 7 of the housing 2 adjoins a floor of the passenger compartment.

In order to then produce a housing 2 with properties that are improved compared to known housings, this housing 2 with the comparatively large-area cover 7 has at least one of the six outer surfaces 9 of the housing 2 embodied as a shielding device 3. The shielding device 3 is flame-resistant and flame-retardant in that it is embodied as a direct shielding system and comprises an insulating layer 10 and, facing a free outer space, a metallic support layer 11, as depicted in the cross-sectional view in FIG. 3.

In this exemplary embodiment, the shielding device 3 does not itself constitute part of the housing 2, but is attached to an already existing outer surface 9 of the housing 2 on the outside. In this case, the shielding device 3 is anchored to the surface of the cover 7 by means of an adhesive so that the housing 2 with the high-voltage battery system 1 as a complete structural unit requires no further intervention. Depending on the requirements of a particular application, however, connections by means of screws, rivets, or welds can also be provided if the shielding device 3 cannot be permanently anchored to or on the cover 7 by means of clamping or folding.

In this example, the insulating layer 10 is embodied as a ceramic fiber mat with a high thermal insulating effect and correspondingly high thermal resistance with low flammability. A structuring of the metallic support layer 11, which in this example is embodied as an aluminum sheet, increases structural rigidity and also has a positive influence on a damping of interference signals, which are subjectively perceived as ugly interference phenomena in the form of noise, vibrations, and/or roughness in a transition range from approx. 20 Hz to approx. 100 Hz and can at least be felt or also heard as shrill whistling tones with frequencies of up to approx. 4,500 Hz. The interference signals in this case do not necessarily have to be generated by the electrical circuit itself; they are damped by the shielding device 3 regardless of their origin. The material of the insulating layer 10 has also been selected with an internal structure so as to have the passive property of producing a very pronounced damping effect in certain frequency ranges. For applications in a low-temperature range, there is therefore the option of using a foam made of insulating plastic for the insulation material. In other temperature ranges corresponding to the specific material properties, aerogels and/or ceramic or mineral foams should be provided as insulation materials. In these cases, the above-mentioned advantages are achieved with little need for additional installation space and only a marginal increase in the overall weight of the housing 2.

A high thermal resistance of the insulating layer 10 generates a directional heat flow \dot{Q}, which is not the same in all spatial directions. Thus only a small portion of the thermal losses Q that occur in elementary storage cells 12 flows by means of a heat flow \dot{q} to the support layer 11 and a much larger portion flows by means of the heat flow \dot{Q} to a cooling device 4 positioned opposite from the shielding device 3 on the housing 2 in order to be dissipated there as an accumulated quantity of heat Qₜₒₜ.

In an exemplary embodiment not shown in detail in the drawings, the shielding device 3 extends beyond the cover 7 to all of the adjacent side surfaces or outer surfaces 9. This means that one side surface 9 of the housing 2 is also better thermally decoupled from a surrounding region in which external connections 13 of the HV and LV level of the high-voltage battery storage device 1 itself and connections 14 for the inlet and outlet of the cooling device 4 are provided on the remaining side surface 9 of the tray 5 of the cuboid housing 2. Overall, this extension of the shielding device 3 achieves the fact that in an installed state, partial heat flows cannot couple a higher portion of heat loss from the elementary storage cells 12 via the housing 2, e.g. into the chassis of the vehicle. This further enhances a focusing of heat removal via the cooling device 4, which improves the efficiency of the whole cooling system.

In addition to a thermal resistance, the shielding device 3 also has a high electrical resistance due to the insulating layer 10 that is oriented toward the electronic circuit, in this case the entire interior of a battery storage device 1. Sporadic excessively high temperatures in an elementary storage cell 12 therefore also cannot directly cause a short circuit to a chassis and/or an introduction of large quantities of heat by means of a heat flow \dot{Q} into a passenger compartment of a vehicle. Due to the thermal and electrical stability of the insulating layer 10, this condition is maintained not only during regular continuous operation, but also over a sufficiently long period of time in the event of a thermal runaway of an elementary storage cell 12, which usually results in a chain reaction in other elementary storage cells 12. A shielding device 3 thus also extends the evacuation time in the event of a thermal runaway effect in the high-voltage battery storage device 1 of an electric vehicle, thus increasing safety inside a passenger compartment.

As additional safety in the region of a vehicle floor, toward which a large surface of a battery is always oriented, an intermediate layer 15 shown in FIG. 3 is provided as a mechanical protection for the cooling device 4. The intermediate layer 15 is composed of a Kevlar layer in order to reliably prevent a leakage from a cooling circuit due to penetration by a nail or a hole made by a stone.

In addition, a housing 2 around an electrical circuit 1 can also be formed by the shielding device 3 itself, which is equipped with a heat sink 4, without a housing 2 having to be provided in advance. The advantageous properties enumerated and described above can therefore also be constructively used as a so-called retrofit for existing electrical components that generate heat loss.

1. A housing or portion of a housing for an electronic circuit, the housing or portion of a housing comprising:
at least one outer surface, which is a shielding device with an insulating layer facing the electronic circuit and a metallic outer layer, and
a heat sink.

2. The housing or portion of a housing according to claim 1, wherein the at least one outer surface of the housing or portion of the housing is provided with the shielding device or is formed by the shielding device.

3. The housing or portion of a housing according to claim 1, wherein the at least one outer surface of the housing or portion of the housing is provided with the heat sink or is formed by the heat sink.

4. The housing or portion of a housing according to claim 1, wherein the shielding device and/or the heat sink are flame-resistant and/or flame-retardant.

5. The housing or portion of a housing according to claim 1, wherein the shielding device and/or the heat sink have vibration-damping and/or acoustically damping properties tailored to a specific application.

6. The housing or portion of a housing according to claim 1, wherein the shielding device and the heat sink are embodied to force a directed heat flow within the closed housing.

7. The housing or portion of a housing according to claim 1, wherein the shielding device and the heat sink are positioned complementary to each other.

8. The housing or portion of a housing according to claim 1, wherein the shielding device and the heat sink are positioned opposite from each other on the housing.

9. The housing or portion of a housing according to claim 1, wherein the shielding device and the heat sink are positioned on a portion of the housing.

10. The housing or portion of a housing according to claim 1, wherein the shielding device and/or the heat sink comprise a cover and at least partially adjoining side surfaces of the housing or of the portion of the housing.

11. The housing or portion of a housing according to claim 10, wherein the shielding device and/or the heat sink are embodied as a heat sink on a bottom and/or a cover adjacent to side surfaces of the housing.

12. The housing or portion of a housing according to claim 11, wherein the heat sink has a safety material which is positioned in a form of a layer between the metallic outer layer and a layer for heat dissipation.

13. The housing or portion of a housing according to claim 12, wherein the shielding device has a safety material which is positioned in a form of a layer between the metallic outer layer and the insulating layer as additional mechanical protection.

14. The housing or portion of a housing according to claim 12, wherein the shielding device and/or the heat sink is equipped with Kevlar or another safety material for increased safety from mechanical penetration.

15. The housing or portion of a housing according to claim 1, wherein the electronic circuit is an electrical system component of a vehicle.
